(19) United States
(12) Patent Application Publication
(10) Pub. No.: US 2011/0207332 A1
(43) Pub. Date: Aug. 25, 2011

(54) THIN FILM COATED PROCESS KITS FOR SEMICONDUCTOR MANUFACTURING TOOLS

(75) Inventors: Hsu-Shui LIU, Pingjhen City (TW); Yeh-Chieh WANG, Hsinchu City (TW); Jiun-Rong PAI, Jhubei City (TW)

(73) Assignee: TAIWAN SEMICONDUCTOR MANUFACTURING CO., LTD., Hsin-Chu (TW)

(21) Appl. No.: 12/778,255

(22) Filed: May 12, 2010

Related U.S. Application Data
(60) Provisional application No. 61/308,015, filed on Feb. 25, 2010.

(51) Int. Cl. H01L 21/465; C23C 16/44; C23C 16/06

(52) U.S. Cl. 438/719; 427/255.31; 438/710; 156/345.1; 156/345.48; 427/248.1; 134/1.1; 257/E21.485

(57) ABSTRACT

A plasma processing apparatus used in semiconductor device manufacturing includes a process kit formed of insulating materials such as quartz and coated with a Y₂O₃ coating. The Y₂O₃ coating is a thin film formed using suitable CVD or PVD operations. The Y₂O₃ coating is resistant to degradation in fluorine etching chemistries commonly used to etch silicon in semiconductor manufacturing. The plasma processing apparatus may be used in etching, stripping and cleaning operations. Also provided in another embodiment is a plasma processing apparatus having a quartz process kit coated with a sapphire-like film.

### RELATED APPLICATION

This application is related to and claims priority of U.S. Provisional Application Ser. No. 61/308,015 entitled THIN FILM COATED PROCESS KITS FOR SEMICONDUCTOR MANUFACTURING TOOLS, filed Feb. 25, 2010, the contents of which are incorporated herein by reference as if set forth in their entirety.

### FIELD OF THE INVENTION

The present invention relates, most generally, to semiconductor device manufacturing. More particularly, the present invention relates to semiconductor manufacturing tools and methods and systems for reducing degradation of such tools.

### BACKGROUND

Plasma etching operations are used very frequently in the rapidly advancing art of semiconductor device manufacturing. Various processing operations involve RIE (reactive ion etching) or other plasma etching operations to etch materials formed on a semiconductor device, typically to create a pattern in a material layer formed on a semiconductor substrate. Plasma cleaning operations are also commonly used in the semiconductor device manufacturing industry and in conjunction with various materials used in semiconductor device manufacturing. Cleaning operations may, for example, include stripping operations used to remove a blanket film of material from a semiconductor device. Either type of plasma processing operation involves the plasma reacting to remove a material formed on a substrate. One common plasma processing operation involves the use of fluorine-based gases such as NF₃, CF₄, C₃F₆, C₃F₈ CHF₃ and various other CₓF_{y} and other fluorine-based chemistries for etching and/or cleaning operations. Fluorine-based chemistries are commonly used, for example, to etch silicon such as polysilicon and are therefore very frequently used as etching and cleaning chemistries in semiconductor device manufacturing.

Within a plasma processing chamber is a process kit, i.e. the quartz or other ceramic or insulating hardware typically included within a plasma processing chamber and which influences the impedance of the chamber. The process kit typically includes a focus ring, one or more windows, and a large plate above the plasma or various other components, and therefore constitutes a significant amount of surface area within the process chamber. The materials typically used for process kits are prone to attack and degradation in fluorine-based chemistries. Such materials that are prone to attack include quartz, silicon, alumina and anodized parts and as a result, these parts have short lifetimes and require frequent and lengthy conditioning of the process chambers within which they are used. Quartz, for example, is a favored material for process kits but is subject to erosion and degradation in fluorine-based etching and cleaning chemistries. As the quartz process kit erodes, it causes particle contamination, it alters the impedance of the chamber and therefore the plasma performance, and it needs to be replaced. As such, some process kits are spray coated, oxidized or coated with a material such as a ceramic to improve the integrity of the process kit in the plasma chemistry. By coating the exposed surfaces of the process kit with materials other than designed by the manufacturer, however, the impedance of the process chamber is undesirably changed and therefore the etch characteristics and cleaning characteristics of the tool are compromised, i.e., process shifting occurs. Moreover, conventional coatings are subject to cracking, peeling and delamination which produce particle contamination.

It would therefore be desirable to provide a process kit that is resistant to degradation in the plasma chemistries in which it is utilized.

### SUMMARY OF THE INVENTION

According to one aspect, provided is a semiconductor manufacturing apparatus comprising a plasma processing chamber including therein a process kit formed of quartz and having a yttria (Y₂O₃) coating on exposed surfaces thereof. The semiconductor manufacturing apparatus may further include a gas delivery system that delivers a fluorine chemistry to the plasma processing chamber, and RF generation means that generates a fluorine-containing plasma within the plasma processing chamber.

According to another aspect, provided is a semiconductor manufacturing apparatus comprising a plasma processing chamber including therein a process kit with quartz components and having a sapphire-like coating on exposed surfaces of the quartz components.

In a semiconductor manufacturing plasma etching apparatus including an etching chamber and a process kit formed of quartz, another aspect of the invention is the improvement comprising coating exposed surfaces of the process kit with Y₂O₃ using at least one of CVD (chemical vapor deposition) and PVD (physical vapor deposition).

According to another aspect, provided is a method for manufacturing a semiconductor processing apparatus. The method comprises providing a plasma processing chamber, providing a quartz process kit within the plasma processing chamber, and forming a Y₂O₃ coating on exposed surfaces of the quartz process kit.

### BRIEF DESCRIPTION OF THE DRAWING

The present invention is best understood from the following detailed description when read in conjunction with the accompanying drawing. It is emphasized that, according to common practice, the various features of the drawing are not necessarily to scale. On the contrary, the dimensions of the various features are arbitrarily expanded or reduced for clarity. Like numerals denote like features throughout the specification and drawing.

FIG. 1 is a cross-sectional view showing an exemplary plasma etching process chamber according to the invention; and

FIG. 2 is a perspective, top view of an exemplary process chamber according to the invention.

### DETAILED DESCRIPTION

One aspect of the invention provides for a yttria, Y₂O₃ coating formed using chemical vapor deposition, CVD, or physical vapor deposition, PVD, on surfaces of a process kit inside a plasma processing chamber that may be used for plasma etching, plasma cleaning, or both. Other suitable thin film deposition processes may be used in other exemplary embodiments. The plasma processing chamber may be a chamber in any of various plasma processing apparatuses made by various manufacturers that are commercially available and used in the semiconductor manufacturing industry. The plasma processing chamber may be a chamber that is primarily used for etching processes or cleaning processes and the processing chamber may be a chamber dedicated to a fluorine-based processing chemistry. As referred to herein, process kit refers to the insulating components of the process chamber apparatus that are capable of reducing or eliminating electrical arcing from exposed metal in the chamber. The process kit may include various components such as an insulating plate, a focus ring, and one or more windows that enable a viewer to see inside the process chamber. The process kit may be formed of various suitable materials such as insulating materials including but not limited to quartz and various ceramics. The coating is a thin film coating advantageously formed of yttria, Y₂O₃ and according to other aspects, the coating may be a sapphire-like coating formed using CVD or PVD or other suitable thin film deposition methods.

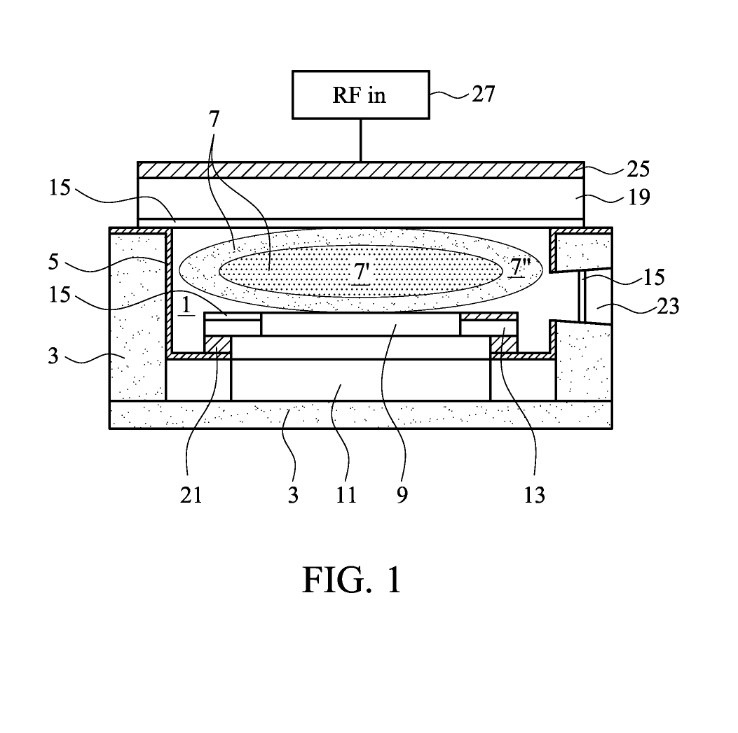

FIG. 1 provides an overview of an exemplary application of the inventive coating. FIG. 1 shows process chamber 1 disposed within chamber body 3. Chamber body 3 may be formed of various suitable sturdy materials of high strength. Chamber liner 5 is also formed of various suitable materials available in the art of semiconductor processing apparatuses. The process chamber liner 5 may be formed of aluminum or other suitable materials and may include an anodized coating, a ceramic spray coating or yttria spray coating. In other exemplary embodiments, other methods for forming the aforementioned coatings on process chamber liner 5 that forms the internal walls of process chamber 1, may be used.

Process chamber 1 may be used for various applications such as various plasma processing operations including but not limited to etching, stripping, and cleaning. Plasma 7 including concentrated high-intensity plasma area 7′ and outer low-intensity plasma area 7″ may be produced using various suitable plasma generating operations. The distribution and configuration of high-intensity plasma area 7′ can be defined by tuning the pressure in process chamber 1 and therefore high-intensity plasma area 7′ and low-intensity plasma area 7″ may take on different relative configurations in other exemplary embodiments. According to one exemplary embodiment, the plasma processing operation may be a reactive ion etching, RIE, plasma etching operation. Plasma 7 may be generated using conventional means. In the illustrated embodiment, the plasma generation may be effectuated by a potential difference between electrode 25 and chuck 9/pedestal 11. RF generating means 27 may be advantageously coupled to electrode 25 according to one exemplary embodiment. In other exemplary embodiments, a coil (not shown) may be used in place of electrode 25.

Chuck 9 may be any of various suitable chucks for retaining a substrate as used in the semiconductor manufacturing industry and in one exemplary embodiment, chuck 9 may be an electrostatic chuck, ESC. Pedestal 11 may be formed of various suitable materials. Various conventional means (not shown) may be used to deliver gases to process chamber 1 for use in the plasma to be generated in process chamber 1. Various combinations of gases may be used. According to one exemplary embodiment, process chamber 1 may be utilized for etching or removing silicon, e.g., polysilicon etching, and included among the plasma processing gases may be fluorine-based etching/cleaning gases such as NF₃, CF₄, C₃F₆, C₃F₈, CHF₃ and various other CₓF_{y} and other fluorine-based etch chemistries. The fluorine-based chemistries may include various other carrier and/or reactive gases along with the fluorine etching species in other exemplary embodiments.

In the illustrated embodiment, the process kit includes quartz plate 19, focus ring 13 and window 23. Quartz plate 14 is seen to be generally parallel to the upper surface of chuck 9 but other configurations may be used in other exemplary embodiments. In the illustrated embodiment, the process kit may be a quartz process kit but process kits formed of other materials may also be used. Focus ring 13 rests on ceramic base ring 21 and the edge of chuck 9. In each of the components of the process kit, thin film coating 15 is disposed on the surface of the process kit component that is exposed to the plasma. Coating 15 is formed on the respective surfaces of the process kit components as a thin film coating using another coating apparatus and advantageously prior to the installation of the process kit within process chamber 1. The coating apparatus used to form coating 15 may be a PVD, physical vapor deposition, or a CVD, chemical vapor deposition apparatus sized to accommodate the various components of the process kit. Coating 15 is a thin film coating and may have a thickness less than 20 microns according to one exemplary embodiment but other thicknesses may be used in other exemplary embodiments. In one exemplary embodiment, coating 15 may include thickness of 5 microns. In one exemplary embodiment, coating 15 may be a yttria, i.e., Y₂O₃ coating and in other exemplary embodiments, coating 15 may be a sapphire-like coating formed using PVD or CVD or other suitable thin film deposition processes.

Coating 15 is resistant to attack from the etch or cleaning chemistries used in plasma 7. In one exemplary embodiment, Y₂O₃ coating 15 is resistant to attack from fluorine-based chemistries. Coating 15 also provides the advantages of prolonging the lifetime of the process kit, e.g., window 23, focus ring 13 and quartz plate 19. The apparatus with process chamber 1 is used to carry out various etching and cleaning plasma operations. Because coating 15 is resistant to attack/degradation in the etching plasma, particle defect levels are reduced and the time needed for conditioning process chamber 1 after a chamber clean, for example, is reduced. Due to the material and the thin film nature of coating 15, the overall impedance of process chamber 1 is maintained and little or no process shift is experienced, i.e. the plasma etching and plasma cleaning characteristics are uniform throughout a run and repeatable on a run-to-run basis and the processing chamber performs according to design and according to designs with uncoated process kit designed to be used within the chamber.

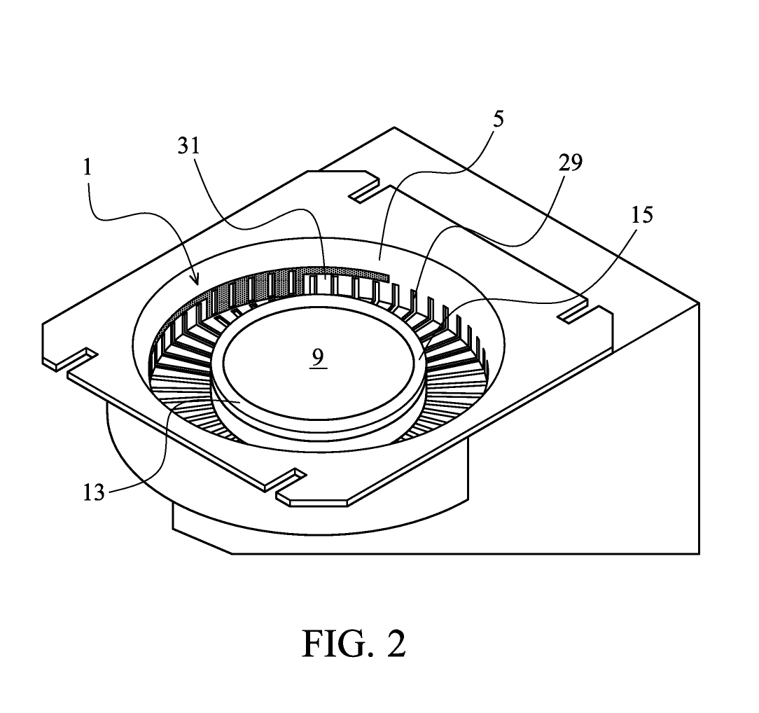

FIG. 2 is a perspective view showing a portion of an exemplary embodiment of process chamber 1. Liner 5 serves as a baffle as the bottom portion of liner 5 consists of ribs 31 and gaps 29 in between the ribs that may be used to maintain a uniformity in gas flow during pump down or processing. Focus ring 13 of the process kit laterally surrounds chuck 9 and is coated with coating 15, as are other exposed surfaces of the process kit (not shown in FIG. 2).

The preceding merely illustrates the principles of the invention. It will thus be appreciated that those skilled in the art will be able to devise various arrangements which, although not explicitly described or shown herein, embody the principles of the invention and are included within its spirit and scope. For example, although the illustrated embodiment is a single substrate process chamber, the coating of the invention may be applied to process kits used in batch etching process apparatuses in various other exemplary embodiments. It should also be understood that the process kit may consist of various and other components in other exemplary embodiments. Furthermore, the process kit formed of a quartz material is intended to be exemplary only and the inventive coating may be applied to process kits formed of various other materials in other exemplary embodiments.

Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure.

This description of the exemplary embodiments is intended to be read in connection with the figures of the accompanying drawing, which are to be considered part of the entire written description. In the description, relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description and do not require that the apparatus be constructed or operated in a particular orientation. Terms concerning attachments, coupling and the like, such as “connected” and “interconnected,” refer to a relationship wherein structures are secured or attached to one another either directly or indirectly through intervening structures, as well as both movable or rigid attachments or relationships, unless expressly described otherwise.

Although the invention has been described in terms of exemplary embodiments, it is not limited thereto. Rather, the appended claims should be construed broadly, to include other variants and embodiments of the invention, which may be made by those skilled in the art without departing from the scope and range of equivalents of the invention.

What is claimed is:

1. A semiconductor manufacturing apparatus comprising a plasma processing chamber including therein a process kit formed of quartz and having a Y₂O₃ coating on exposed surfaces thereof.

2. The semiconductor manufacturing apparatus as in claim 1, wherein said process kit includes a focus ring laterally surrounding a chuck.

3. The semiconductor manufacturing apparatus as in claim 1, wherein said process kit includes at least a quartz disk disposed over a chuck, and a window.

4. The semiconductor manufacturing apparatus as in claim 3, wherein said quartz disk is disposed between said chuck and an electrode or coil.

5. The semiconductor manufacturing apparatus as in claim 1, wherein said Y₂O₃ coating is deposited on said exposed surfaces using one of CVD (chemical vapor deposition) and PVD (physical vapor deposition).

6. The semiconductor manufacturing apparatus as in claim 1, wherein said Y₂O₃ coating includes a thickness less than 20 microns.

7. The semiconductor manufacturing apparatus as in claim 1, further comprising a gas delivery system that delivers a fluorine chemistry to said plasma processing chamber, and RF generation means that generate a fluorine-containing plasma within said plasma etching chamber.

8. The semiconductor manufacturing apparatus as in claim 1, wherein internal walls of said plasma processing chamber include a coating of yttria thereon.

9. A semiconductor manufacturing apparatus comprising a plasma etching chamber including therein a process kit including quartz components and having a coating on exposed surfaces of said quartz components, said coating being a yttria coating or a sapphire-like coating.

10. The semiconductor manufacturing apparatus as in claim 9, wherein said coating comprises said sapphire-like coating and is deposited on said exposed surfaces using one of CVD (chemical vapor deposition) and PVD (physical vapor deposition).

11. The method as in claim 10, further comprising a Y₂O₃ coating on internal walls of said plasma etching chamber.

12. A method for manufacturing a semiconductor processing apparatus, said method comprising:
providing a plasma processing chamber;
providing a quartz process kit within said plasma processing chamber; and
forming a Y₂O₃ coating on exposed surfaces of said quartz process kit.

13. The method as in claim 12, wherein said forming a Y₂O₃ coating comprises one of CVD (chemical vapor deposition) and PVD (physical vapor deposition).

14. The method as in claim 12, further comprising coating inner surfaces of said plasma processing chamber with a Y₂O₃ film.

15. The method as in claim 12, wherein said forming comprises forming said Y₂O₃ coating to a thickness of no more than 20 microns.

16. The method as in claim 12, wherein said process kit comprises a focus ring laterally surrounding a chuck, a quartz disk disposed over said chuck, and a window.

17. The method as in claim 12, further comprising generating a fluorine-containing plasma in said processing chamber.

18. The method as in claim 17, further comprising etching or cleaning a film on a semiconductor substrate disposed in said chamber, using said plasma.

19. The method as in claim 18, wherein said film comprises polysilicon.

20. The method as in claim 12, wherein said forming a Y₂O₃ coating takes place in another processing tool and before said quartz process kit is disposed within said plasma processing chamber.
